(19) United States
(12) Patent Application Publication
(10) Pub. No.: US 2020/0020538 A1
(43) Pub. Date: Jan. 16, 2020

(54) PATTERNED DISCRETE NANOSCALE DOPING OF SEMICONDUCTORS, METHODS OF MANUFACTURE THEREOF AND ARTICLES COMPRISING THE SAME

(71) Applicants: Rohm and Haas Electronic Materials LLC, Marlborough, MA (US); The Regents of the University of California, Oakland, CA (US)

(72) Inventors: Yuanyi Zhang, Santa Barbara, CA (US); Reika Katsumata, Goleta, CA (US); Mingqi Li, Shrewsbury, MA (US); Bhooshan C. Popere, Marlborough, MA (US); Andrew T. Heitsch, Angleton, TX (US); Peter Trefonas, III, Medway, MA (US); Rachel A. Segalman, Santa Barbara, CA (US)

(21) Appl. No.: 16/032,695

(22) Filed: Jul. 11, 2018

(51) Int. Cl. H01L 21/225; H01L 21/22; H01L 21/324

(52) U.S. Cl. CPC H01L 21/2254; H01L 21/324; H01L 21/2225

(57) ABSTRACT

Disclosed herein is a method for doping a substrate, comprising disposing a composition comprising a dopant-containing copolymer and a solvent on a substrate; and annealing the substrate at a temperature of 750 to 1300° C. for 0.1 second to 24 hours to diffuse a dopant into the substrate; wherein the dopant-containing copolymer comprises a non-dopant-containing polymer and a dopant-containing polymer; and where the dopant-containing polymer is a polymer having a covalently or ionically bound dopant atom and is present in a smaller volume fraction than the non-dopant-containing polymer.

### BACKGROUND

This disclosure relates to patterned discrete nanoscale doping of semiconductors, methods of manufacture therefore and to articles comprising the same. More specifically, this disclosure relates to the patterned discrete nanoscale doping of a substrate via a dopant-containing copolymer film that is disposed upon the substrate.

One of the challenges of scaling electronic devices down to the nanometer regime (sizes less than 100 nanometers (nm)) is achieving controlled doping of semiconductor materials in the sub-10 nanometer size range. For example, with transistor gate lengths fast approaching sub-10 nm size range, highly conductive ultra-shallow junctions on the nanometer length scale are used to scale down transistor size to achieve faster transistor speeds and higher packing densities. Furthermore, a wide range of advanced non-planar or “3D” device designs, such as FINFET or nanowire transistors, have been demonstrated to provide improved gate electrode contact in a limited area and thus better control of the channel, allowing very little current to leak through the body when the device is in the ‘off’ state. This, in turn, enables the use of lower threshold voltages and results in better performance and power. The control of uniform conformal doping in these “3D” devices is difficult.

CMOS (Complementary Metal Oxide Semiconductor) technology is important for modern semiconductor fabrication. In the fabrication process of CMOS, a NMOS (negative channel metal-oxide-semiconductor) and a PMOS (positive channel metal-oxide-semiconductor) need to be generated on the same substrate side-by-side to make it functional. NMOS uses a n-doped well resides inside a deeper, wider, light p-doped region and vice versa for PMOS. This type of architecture design uses a respective doping process on the same area, thus presenting an even more difficult challenge for the fabrication of non-planar 3D devices.

Current methods are not suitable for doping to depths of less than 10 nm. Ion implantation involves the bombardment of silicon substrates with high-energy dopant ions that replace silicon atoms in the substrate lattice. However, the process also produces point defects and vacancies in the lattice, which interact with the dopants to broaden the junction profile, thereby limiting the formation of sub-10 nm doping profiles. Furthermore, ion implantation is generally directional, making it incompatible with non-planar, nanostructured materials. On the other hand, conventional solid-source diffusion procedures lack control and uniformity when doping is to be conducted at depths of less than 10 nm.

Monolayer doping procedures overcome the difficulties of current technologies and achieve high-quality, sub-5 nm doping profiles with high areal uniformity. During this procedure, a highly uniform, covalently bonded monolayer of dopant-containing small molecules is formed on silicon surfaces. In a subsequent thermal annealing step, the dopant atoms are diffused into the silicon lattice. This approach has resulted in the demonstration of the shallowest junctions reported to date with low sheet resistivity for both p- and n-type doping, and is compatible with non-planar, restricted-dimension nanostructured substrates. However, the monolayer doping strategy uses a couple of steps that are cumbersome. Firstly, deposition of the dopant-containing small molecules is carried out in an oxygen free atmosphere (i.e., in an inert atmosphere or in a vacuum) to prevent oxidative contamination. In addition, a silicon oxide capping layer is evaporated on top of the surface-functionalized silicon substrate before the annealing step in order to achieve efficient diffusion of the dopant atoms into the silicon substrate. The evaporation of the capping layer requires high vacuum of approximately ˜10⁻⁶ Torr.

Accordingly, it is desirable to develop a process for doping a substrate in ambient conditions without using a high vacuum and without using etching.

### SUMMARY

Disclosed herein is a method for doping a substrate, comprising disposing a composition comprising a dopant-containing copolymer and a solvent on a substrate; and annealing the substrate at a temperature of 750 to 1300° C. for 0.1 second to 24 hours to diffuse a dopant into the substrate; wherein the dopant-containing copolymer comprises a non-dopant-containing polymer and a dopant-containing polymer; and where the dopant-containing polymer is a polymer having a covalently or ionically bound dopant atom and is present in a smaller volume fraction than the non-dopant-containing polymer.

Disclosed herein too is a composition comprising a dopant-containing copolymer; wherein the dopant-containing copolymer comprises a non-dopant-containing polymer and a dopant-containing polymer; and where the dopant-containing polymer is a polymer having a covalently bound dopant atom and is present in a smaller volume fraction than the non-dopant-containing polymer; and a solvent.

Disclosed herein too is a method comprising mixing in a solvent, a reactive species with an unsaturated group that is devoid of a dopant, a dopant-containing monomer with an unsaturated group, an initiator and a reversible addition fragmentation chain transfer agent; and reacting the reactive species with the unsaturated group that is devoid of a dopant, the dopant-containing monomer with the unsaturated group, the initiator and the reversible addition fragmentation chain transfer agent to form a copolymer.

### BRIEF DESCRIPTION OF THE FIGURES

FIG. 1 shows a transmission electron micrograph of a block copolymer film cross-section. The marker represents 100 nanometers;

FIG. 2 is a graph showing the boron concentration versus depth in silicon substrates that are doped with films containing different concentrations of the dopant; and

FIG. 3 is a bar graph showing the comparison of sheet resistance between homogeneous and patterned doping of silicon substrates.

### DETAILED DESCRIPTION

Disclosed herein are compositions for doping substrates with ultra-shallow junctions that are less than 5 nanometers from a surface of the substrate. The substrate prior to doping may be electrically insulating or semiconducting. The composition comprises a copolymer that can undergo phase separation into two or more discrete phases upon being disposed upon and annealed on a substrate. The copolymer comprises at least one polymer that contains a dopant (i.e., the repeat units of one of the polymers of the block copolymer comprises a dopant). When the copolymer undergoes phase separation, at least one of the domains is dopant-rich, while the other domains are relatively dopant-free. Upon annealing, the block copolymer undergoes degradation. The dopant from the dopant-rich domains however, undergoes shallow diffusion into the substrate thus facilitating the formation of dopant domains within the substrate. The domains within the substrate are formed at depths of less than 5 nanometers (referred to herein as ultra-shallow domains). The substrate with the ultra-shallow domains disposed therein is now a semi-conducting substrate.

Disclosed herein too is a method of manufacturing semiconductors with ultra-shallow junctions that include one or a series of doping processes at the same area, by disposing a phase separating dopant-containing copolymer on the substrate and annealing the substrate at a temperature that facilitates degradation of the copolymer and diffusion of the dopant into the substrate. The method results in the formation of ultra-shallow junctions (junctions that are less than 5 nanometers from a surface of the substrate).

During the past two decades, many efforts have been made to overcome the intrinsic optical resolution limit of conventional 193 nm immersion lithography and to precisely control the location of dopants. Although single-ion implantation has demonstrated promising results, the prohibitive cost and low throughput have made it challenging on an industrial scale. Ion implantation can dope on a large area, but it suffers from severe crystal damage, which can be corrected by thermal annealing at the cost of non-uniform junctions. Monolayer doping, on the other hand, can precisely control the dosage and junction depth, but lacks control over the lateral distribution of dopants.

The disclosed method is advantageous in that extremely small feature sizes and precise control over the spatial distribution of dopants in semiconductors can be effected. With very small feature sizes and the 3-dimensional surface topography of new device designs such as FinFET and Nanowire-FET, the control over the spatial distribution of dopants in semiconductors is hard to effect by other conventional methods. This method is also advantageous in that a vacuum is not desirable during the process. The copolymer film acts as its own capping layer thereby eliminating the need for using a capping layer that is used in other commercially available comparative processes. In other words, the method is free of a step of forming an oxide capping layer over the polymer film prior to the annealing step. By using low annealing temperatures and low annealing times, doped junctions as shallow as 5 nanometers can be obtained in the substrate. The method is particularly beneficial, for example, for forming highly conductive ultra-shallow junctions for source/drain transistor gates and for doping silicon nanostructures such as FINFET, or nanowires to produce a variety of 3-D miniaturized electronic devices. The copolymer film is also referred to herein as a polymer coating or a polymer layer.

The substrate is a semiconducting substrate. Examples of suitable semiconducting substrates are amorphous silicon, germanium, gallium, gallium arsenide, silicon germanium, silicon carbide, mixtures of arsenic, selenium and tellurium, and the like. An exemplary semiconductor for use as the substrate is silicon. The substrate surface may be a flat planar surface or alternatively, may be textured (i.e., be a surface with a 3-dimensional profile).

The substrate is coated with a polymeric film that comprises a copolymer that contains the dopant with which the substrate is doped. In an embodiment, the copolymer comprises a first polymer and a second polymer, one polymer of which comprises the dopant. Dopants may include boron, phosphorus, arsenic, bismuth, antimony, gallium, or combinations thereof

Both p- and n-type dopants may be delivered to a substrate if desired. P-type dopants include boron, aluminum, gallium, indium, or combinations thereof, whereas n-type dopants include phosphorus, arsenic, bismuth, lithium, or combinations thereof

The dopant is either ionically or covalently bonded to the copolymer. In a preferred embodiment, the dopant is covalently bonded to one of the polymers in the copolymer and will hereinafter be termed the dopant-containing polymer. In an embodiment, the dopant is part of the polymer backbone, while in another embodiment the dopant is a substituent on the polymer backbone. In yet another embodiment, the dopant is part of the polymer backbone as well as a substituent on the polymer backbone. In a preferred embodiment, the dopant is either phosphorus or boron and polymers containing these dopants will hereinafter be referred to as boron-containing polymers or phosphorus-containing polymers.

The dopant-containing copolymer can be a thermoplastic polymer, a blend of thermoplastic polymers, a thermosetting polymer, or a blend of thermoplastic polymers with thermosetting polymers. The dopant-containing polymer may also be a blend of dopant-containing copolymers, dopant-containing terpolymers, or a combination thereof. The dopant-containing copolymer can also be an alternating, block, random or graft copolymer. The dopant-containing copolymers may be linear, dendritic, star, branched or cyclic copolymers, or the like. In an embodiment, the thermosetting film (containing the dopant) may be applied to the substrate as a thermoplastic film and can undergo crosslinking (i.e., become a thermoset) during the annealing of the film. A preferred copolymer is a block copolymer.

As noted above, the copolymer comprises a first polymer and a second polymer, one polymer of which comprises the dopant. For purposes of this disclosure the second polymer will be referred to as the dopant-containing polymer. The dopant-containing polymer is the minority polymer, i.e., it is present in a lower amount in the copolymer than the non-dopant-containing polymer. The dopant-containing polymer is present in the copolymer in an amount of less than 50 volume percent (vol %), preferably less than 40 vol %, preferably less than 30 vol %, and more preferably less than 25 vol %, based on the total volume of the copolymer.

The first polymer (i.e., the non-dopant-containing polymer) may be a thermoplastic polymer or thermosetting polymer. Examples of the thermoplastic polymers are polyacetals, polyolefins, polyacrylics, polyacrylates, polystyrenes, polyarylsulfones, polyethersulfones, polyphenylene sulfides, polyvinyl chlorides, polytetrafluoroethylenes, polyetherketones, polyether etherketones, polyether ketone ketones, polyphthalides, polyacetals, polyanhydrides, polyvinyl ethers, polyvinyl thioethers, polyvinyl alcohols, polyvinyl ketones, polyvinyl halides, polyvinyl esters, polysulfonates, polysulfides, polythioesters, polysulfones, polyethylene terephthalate, polybutylene terephthalate, ethylene propylene diene rubber, polytetrafluoroethylene, fluorinated ethylene propylene, perfluoroalkoxyethylene, polychlorotrifluoroethylene, polyvinylidene fluoride, or the like, or a combination thereof. A preferred polymer is a polyacrylate.

Examples of thermosetting polymers include epoxy polymers, vinyl polymers, benzocyclobutene polymers, acrylics, alkyds, phenol-formaldehyde polymers, novolacs, resoles, hydroxymethylfurans, diallyl phthalate, or the like, or a combination thereof.

In one embodiment, the first polymer is produced by polymerizing a reactive species that comprises an unsaturated group. Examples of the unsaturated groups include ethylenically unsaturated groups such as vinyl, allyl, allenyl, norbornyl, ethynyl, acrylates, methacrylates, itaconates, maleimides, maleic anhydride and maleic anhydride derivatives, acrylamides, styrenic, vinyl carboxylates, acrylonitriles, or the like.

In one embodiment, the first polymer is produced by polymerization of a reactive species (that is devoid of a dopant) having a structure represented by formula (1):

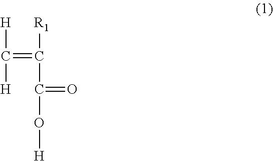

where R₁ is a hydrogen or an alkyl or substituted alkyl group having 1 to 10 carbon atoms. Examples of the reactive species are acrylic acids, acrylates and alkyl acrylates such as, for example, methyl acrylates, ethyl acrylates, propyl acrylates, or the like, or a combination thereof. In an embodiment, the reactive species may be a polyacrylic acid.

In another embodiment, the first polymer is produced by polymerization of a reactive species having a structure represented by the formula (2):

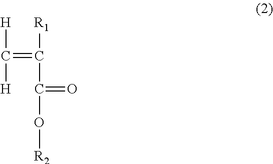

where R₁ is a hydrogen or an alkyl or substituted alkyl group having 1 to 10 carbon atoms and R₂ is a C₁₋₁₀ alkyl, a C₃₋₁₀ cycloalkyl, or a C₇₋₁₀ aralkyl group. Examples of the reactive species of the formula (2) are methacrylic acid, methacrylate, ethacrylate, propyl acrylate, methyl methacrylate, methyl ethylacrylate, methyl propylacrylate, ethyl ethylacrylate, methyl arylacrylate, or the like, or a combination thereof. The term “(meth)acrylate” implies that either an acrylate or methacrylate is contemplated unless otherwise specified.

In yet another embodiment, the first polymer is produced by polymerization of a reactive species having a structure represented by the formula (3):

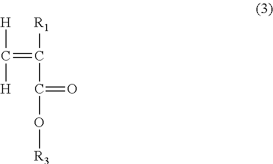

where R₁ is a hydrogen or an alkyl group or substituted alkyl having 1 to 10 carbon atoms and R₃ is a C₂₋₁₀ fluoroalkyl group. Examples of compounds having the structure of formula (3) are trifluoroethyl methacrylate, and dodecafluoroheptylmethacrylate.

The first polymer (i.e., the non-dopant-containing polymer) generally has a number average molecular weight of 1,000 to 50,000 grams per mole; preferably 10,000 to 30,000 grams per mole. The molecular weights disclosed herein are determined by nuclear magnetic resonance (NMR) calculating the conversion of monomers.

Dopants may include boron, phosphorus, arsenic, bismuth, antimony, gallium, arsenic, bismuth, lithium, or combinations thereof. The dopant is either ionically or covalently bonded to the copolymer. Boron-containing polymers and phosphorus-containing polymers are preferred.

Boron-containing polymers can be those derived from the polymerization of organoboron complexes, by the incorporation of organoboron complexes or boron-containing moieties into the backbone of a copolymer or by the incorporation of organoboron complexes or boron-containing moieties as substituents on a polymer backbone.

Examples of organoboron complexes that are used to derive the boron-containing polymers are borane, vinylborane, boronic acid, vinyl boronic acid, vinyl boronic acid pinacol ester, phenyl boronic acid, phenyl boronic acid pinacol ester, 4-(hydroxymethyl)phenylboronic acid pinacol ester, allylboronic acid pinacol ester, borazine, vinylborazine, cyclodiborazane, boron quinolate, boron diketonate, pyrazabole, boron dipyrromethane, carborane, and the like. The aforementioned organoboron complexes may be substituted if desired. Examples of polymers that can be derived by polymerization of the aforementioned organoboron complexes are poly[2-(vinyl)pentaborane)], polyvinylborazine, polyborazylene, poly(cyclodiborazane), cyclodiborazane-containing polymers, boron quinolate polymers, pyrazabole containing polymers, carborane containing polymers, poly(vinylboronic acid), poly(4-(hydroxymethyl)phenylboronic acid pinacol ester, poly(phenylboronic acid), or the like, or a combination thereof. The polymers can be substituted if desired.

A preferred boron-containing polymer for use in the copolymer is poly(4-(4,4,5,5-tetramethyl-1,3,2-dioxaborolan-2-yl)benzyl acrylate). 4-hydroxyphenylboronic acid pinacol ester is used to derive the boron-containing monomer used for the polymerization that produces poly(4-(4,4,5,5-tetramethyl-1,3,2-dioxaborolan-2-yl)benzyl acrylate).

Examples of phosphorus containing complexes that are used to derive the phosphorus containing polymers are dimethyl vinylphosphonate, diethyl vinylphosphonate, diethyl allyl phosphonate, bis(2-chloroethyl) vinyl phosphonate, vinylphosphonic acid, or the like, or a combination thereof. A preferred phosphorus containing polymer poly(diethyl vinylphosphonate) (PDEVP).

The boron-containing polymer for incorporation into the copolymer is generally prepared by first reacting a boron-containing species with an acid halide to produce a boron-containing polymer.

The copolymer may be prepared by addition or condensation polymerization, free radical polymerization, ionic polymerization, or a combination thereof. In an embodiment, free radical polymerization is preferred. In a preferred embodiment, polymerization may occur via reversible addition fragmentation chain transfer (RAFT) polymerization. Reversible addition-fragmentation chain transfer polymerization includes reversible-deactivation radical polymerization. It makes use of a chain transfer agent to afford control over the generated molecular weight and polydispersity during a free-radical polymerization. Reversible addition fragmentation chain transfer polymerization uses thiocarbonylthio compounds such as dithioesters, thiocarbamates, and/or xanthates, to mediate the polymerization via a reversible chain-transfer process. The dithioesters, thiocarbamates or xanthates end up as an end-group of the polymer after polymerization has occurred.

In one embodiment, in one manner of manufacturing the dopant-containing copolymer, a dopant-containing monomer (e.g., boronic acid pinacol ester or diethyl vinylphosphonate) is reacted with an acid chloride in the presence of a solvent and a catalyst in a first reactor. This reaction is conducted to produce a dopant-containing monomer with an unsaturated group.

The reaction is conducted at a temperature from 20 to −30° C., preferably 10 to −10° C., for a period of 10 minutes to 3 hours, preferably 20 minutes to 2 hours. The reaction temperature is brought about cooling the reactor in an ice bath.

The ice bath is removed after a period of 1 to 10 hours and the reaction solution is warmed up to room temperature under ambient conditions and stirred for a period of 1 to 20 hours. The reaction solution may be washed with water and other solvents in order to effect purification of the dopant-containing monomer with the unsaturated group. After drying, solvents are removed from the reaction solution before being subjected to additional solvent removal in a flashing column. The purified reaction product contains the dopant-containing monomer with the unsaturated group. Examples of unsaturated groups are provided above.

To synthesize the copolymer, a reactive species that is devoid of a dopant but has an unsaturated group, a dopant-containing monomer with an unsaturated group, an initiator (e.g., azobisisobutyronitrile (AlBN)) and a reversible addition fragmentation chain transfer agent (e.g., a dithioester such as 2-(dodecylthiocarbonothioylthio)-2-methylpropionic acid (DDMAT)) are first dissolved in a suitable first solvent and degassed via a freeze-pump-thaw. The solution is then heated from 50 to 100° C. for 2 to 6 hours before being quenched in liquid nitrogen. The reaction product is precipitated into a second solvent and dried under a vacuum.

The product, the dopant-containing monomer with the unsaturated group, AIBN and DDMAT are dissolved in a suitable first solvent and degassed via a freeze-pump-thaw. The solution is heated to 50 to 100° C. for 10 to 60 hours before being quenched in liquid nitrogen. The polymers were precipitated into a second solvent and then dried in vacuum. The molecular weight and volume fraction can be varied or controlled by changing the relative equivalence of the acrylate, 4-(4,4,5,5-tetramethyl-1,3,2-dioxaborolan-2-yl)benzyl acrylate and DDMAT.

The dopant-containing polymer generally has a number average molecular weight of 2,000 to 20,000 grams per mole, preferably 4,000 to 10,000 grams per mole. In an embodiment, the reversible addition fragmentation chain transfer agent (e.g., the diothioester such as 2-(dodecylthiocarbonothioylthio)-2-methylpropionic acid) is the end-group of the copolymer chain.

In one embodiment, the weight fraction and the block length of the non-dopant-containing polymer can be varied in order to vary the amount of dopant and the concentration of dopant delivered on a particular portion of the substrate. The dopant-containing polymer is the minority polymer in the copolymer—i.e., it is present in a smaller volume than the non-dopant-containing polymer.

In one embodiment, in one method of doping the semiconducting substrate, the polymer is solubilized in a solvent and disposed on the substrate. The substrate with the polymer disposed thereon is then subjected to annealing (also termed heating) to remove the solvent and to facilitate the doping of the semiconducting substrate.

The first solvent and the second solvent used to facilitate the reaction may be a non-polar or a polar solvent. The solvent that is used to solubilize the dopant-containing copolymer may also be a non-polar or polar solvent. Exemplary non-polar solvents include aromatic hydrocarbons; esters; ethers; and the like. Examples of polar solvents are pentane, cyclopentene, hexane, cyclohexane, benzene, toluene, 1,4-dioxane, chloroform, tetrahydrofuran, diethyl ether, xylene, mesitylene, propylene glycol methyl ether acetate, n-butyl acetate, or the like, or a combination thereof. An exemplary non-polar solvent is tetrahydrofuran.

Examples of the polar solvent includes water, methanol, ethanol, isopropanol, butanol, acetone, methyl ethyl ketone, dichloromethane, or the like, or a combination thereof. Combination of polar and non-polar solvents may be used if desired.

When the dopant-containing polymer is mixed with the solvent, the polymer is present in an amount of 0.0005 to 5 wt %, based on the total weight of the solvent and the dopant-containing polymer. In a preferred embodiment, the polymer is present in an amount of 0.001 to 0.02 wt %, based on the total weight of the solvent and the dopant-containing polymer.

The dopant-containing polymer-solvent solution (hereinafter polymer-solvent solution) may be subjected to agitation and to an increased temperature in order to facilitate solvation of the polymer. The polymer-solvent solution is then disposed upon the substrate surface. The substrate surface may be pre-cleaned by heating or by washing in a solvent or HF solutions prior to disposing the polymer-solvent solution on it.

The dopant-containing polymer-solvent solution may be subjected to purification processes to remove organic, organometallic, nanoparticle, and inorganic impurities. Examples of organic impurities which are undesirable include impurities which cause pinholes, or impurities which cause uncontrolled heterogeneous film morphologies, or impurities which decrease solution stability, or impurities which may cause uncontrolled degradation of the polymer, or undesired crosslinking of the polymer, or degradation of the solvent. Examples of organometallic impurities which are undesirable include impurities which introduce metal or metalloid atoms which can diffuse into the substrate during thermal annealing excluding the desirable dopant atoms; or impurities which may cause uncontrolled degradation of the polymer, or undesired crosslinking of the polymer, or degradation of the solvent. Examples of inorganic impurities include impurities which introduce metal or metalloid atoms which can diffuse into the substrate during thermal anneal excluding the desirable dopant atoms; or impurities which may cause uncontrolled degradation of the polymer, or undesired crosslinking of the polymer, or degradation of the solvent.

The polymer solution may be purified prior to disposing on a substrate by solvent-solvent extraction or an ion exchange process, or by contact with a porous bead which absorbs organic impurities such as activated carbon, or by contact with an absorbant film or membrane or organic brush material or ligand-modified surface which absorbs undesirable impurities. The solvent used to make the polymer solution may be purified though a distillation process or an ion exchange process prior to combining with the polymer to prepare the polymer solution. The polymer used to make the polymer solution may be purified though a precipitation process, or a chromatographic process, or a solvent extraction process, or a solvent rinse process, or a drying process, prior to combining with the polymer to prepare the polymer solution.

The polymer solution is filtered through a filter into a clean carrier vessel or bottle prior to use in order to further eliminate particles, dusts or contaminants which could interfere with film forming properties. A filtration process could use a depth filter or a membrane. Common materials used in said filters, membranes and filter housings include fluorocarbons such as Teflon, nylons, polyethylene, polypropylene, polyolefins, polamides, polyimides, and ionic polymers. In other cases, porous ceramic filters could be used for purification. Contaminant removal mechanisms in said filtration processes include absorption of contaminants and physical prevention and blockage of contaminant passage though pores and small openings.

The polymer-solvent solution may be disposed on the substrate by spin coating, doctor blading, spray coating, dip coating, screen printing, brush coating, and the like. A preferred method for coating the substrate is via spin coating. The solvent can be evaporated from the substrate surface leaving a polymer coating disposed on the substrate. The polymer coating contains the dopant.

The polymer coating acts as its own capping layer, eliminating the need for the high-vacuum evaporation of a metal-oxide layer, such as a silica layer, that is generally used in existing monolayer doping procedures. Furthermore, because the semiconductor substrate is coated with the polymer film rather than being covalently attached, the need for a non-oxidative ambient condition is also eliminated.

The thickness of the polymer coating may range from a few nanometers to a few hundred nanometers (nm), preferably 3 to 250 nm, and more preferably 5 to 200 nm and even more preferably 6 and 50 nm. However, it is contemplated that thinner films could be used, so long as care is taken to avoid pinholes, which would lead to non-uniform doping. Thicker films may also be used if desired if care is taken to minimize the presence of increased organic residue on the semiconductor substrate after annealing. The copolymer may phase separate into spherical domains, lamellar domains, cylindrical domains, or a combination thereof

The substrate along with the polymer coating (comprising the copolymer) disposed thereon is then subjected to annealing to a temperature of 500 to 1500° C., preferably 700 to 1300° C. for a period of 0.1 seconds to 24 hours, preferably for 0.5 seconds to 12 hours, and more preferably for 1 seconds to 3 minutes. Annealing may be conducted by using heating convection, conduction or radiation heating. Convective heating is preferred during the annealing process.

The annealing may be conducted in a vacuum or alternatively in an inert atmosphere. Suitable inert atmospheres include nitrogen, argon, zeon, helium, nitrogen or carbon dioxide. In a preferred embodiment, the annealing is conducted in an inert atmosphere that contains nitrogen.

In another embodiment, the oxidizing may be conducted in an oxidizing atmosphere to facilitate degradation of the copolymer. Oxidizing atmospheres include oxygen, ozone, chlorine, or a combination thereof

The resulting dopant concentration profile within the substrate is a function of the annealing temperature and time for which the substrate and the polymer coating is subjected to diffusion. Other influential factors are the solubility of the dopant molecule in semiconductor substrate at the annealing temperature and the diffusion coefficient of the dopant molecule at the annealing temperature. The annealing time and temperature could thus be varied as needed to achieve the desired dopant profile. Thus, doped junctions as shallow as sub-5 nm may be obtained using appropriately low annealing temperatures and short annealing times.

During the annealing, the any residual solvent from the polymer coating evaporates, leaving behind only the polymer. The dopant from the dopant-containing polymer diffuses into the substrate to a depth of 0.01 to 1000 nm, preferably 0.05 to 100 nm, preferably 0.09 to 50 nm and more preferably 0.1 to 10 nm.

The as-doped substrate my optionally undergo other doping steps with same or different dopant on the same area.

This method of doping facilitates the formation of junctions for source and drain extension regions in electronic devices and articles such as transistors with fast switching speeds and high packing densities. Additional applications include, but are not limited to, transistor gates, nanostructures, diodes, photodetectors, photocells, and integrated circuits.

The method of doping detailed herein is exemplified by the following non-limiting examples.

### EXAMPLE

### Example 1

This example was conducted to demonstrate the synthesizing of the block copolymer comprising a non-dopant-containing polymer and dopant-containing polymer.

The covalent incorporation of dopant atoms into polymer chains is achieved by nucleophilic substitution of acyl chloride and alcohol. The diblock copolymer is synthesized via sequential RAFT (reversible addition fragmentation chain transfer) polymerization. Herein, a cylindrical boron-containing block copolymer (domain spacing=26 nm) was synthesized.

### Synthetic Route for the Boron-Containing Block Copolymer: (a) Synthesis of Bpin, the Boron-Containing Monomer

4-(hydroxymethyl)phenylboronic acid pinacol ester, acryloyl chloride, trimethylamine and 2-(dodecylthiocarbonothioylthio)-2-methylpropionic acid (DDMAT) were purchased from Sigma Aldrich and used as received. 2,2′-azobis(2-methylpropionitrile) (AIBN) and methyl acrylate were also purchased from Sigma Aldrich. AIBN was recrystallized in methanol. The methyl acrylate was purified through a silica gel column containing basic aluminum oxide prior to use. First, 4-(hydroxymethyl)phenylboronic acid pinacol ester (5.00 grams (g) 21.4 mmol) and triethylamine (3.24 g, 32.0 mmol) were dissolved in 200 mL dichloromethane and stirred in an ice bath for 30 minutes. Acryloyl chloride (2.32 g, 25.6 mmol) was dissolved in 30 mL dichloromethane and added to the solution dropwise in the ice bath. The ice bath was removed after one hour and the solution was warmed up to room temperature naturally and stirred overnight. The solution was washed with thrice with water and once with saturated sodium hydrogen carbonate. After drying over magnesium sulfate, the solution was rotovapped to remove all the solvents before going through a flashing column. The mobile phase was a mixture of 16.7 vol % ethyl acetate and 83.3 vol % hexane. The reaction product included a yellow liquid (4 g, yield˜80%), which solidifies immediately upon storing in the fridge. The boron-containing monomer product will be referred to as “Bpin” in these examples.

### Synthetic Route for the Boron-Containing Block Copolymer: (b) Synthesis of the Diblock Copolymer Via Sequential RAFT Polymerization.

To synthesize the block copolymer, methyl acrylate (4.30 g, 50.0 mmol), AlBN (5.5 mg, 0.03 mmol) and DDMAT (61.7 mg, 0.17 mmol) were dissolved in 5 mL dioxane and degassed via 3 freeze-pump-thaw cycles. The solution was heated at 75° C. for 4 hours before quenched in liquid nitrogen. The polymer was precipitated into hexane twice and dried in vacuum to obtain 3 g of poly(methyl acrylate) (PMA). PMA (1.90 g, 0.08 mmol), AIBN (2.7 mg, 0.016 mmol) and the Bpin monomer (1.15 g, 4.0 mmol) were dissolved in 10 mL dioxane and degassed via 3 freeze-pump-thaw cycles. The solution was heated at 75° C. for 48 hours before being quenched in liquid nitrogen. The polymers were precipitated into diethyl ether twice and dried in vacuum to obtain 1.4 g of the final block copolymer product, PMA-b-PBpin (Mn_{PMA}=22.9 kg/mol, Mn_{PBpin}=7.0 k, volume fraction ϕ_{PBpin}=24%). The reaction scheme for both reactions is shown in the schematic below. This process enables the incorporation of dopant atoms in the polymer chains.

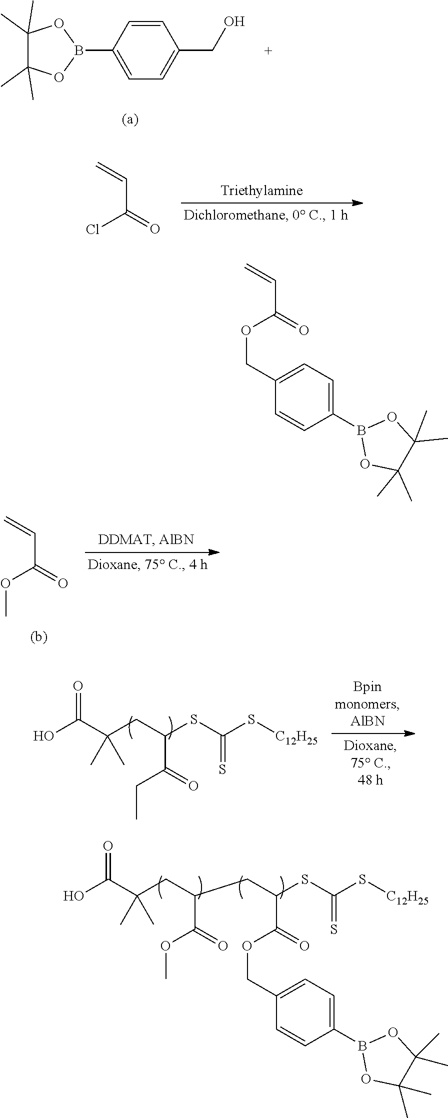

### Example 2

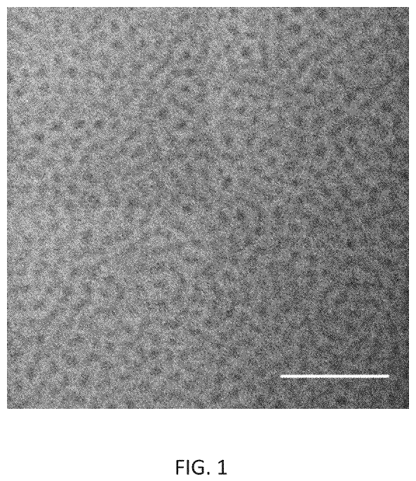

This example was conducted to demonstrate the formation of a film of the block copolymer on a substrate. Block copolymers prepared as in Example 1 were spin-coated onto Si substrates to form films of different thicknesses. 10 mg of PMA-b-PBpin were dissolved in 1 mL toluene. The thickness was tuned by varying the spin speed between 2000 rpm and 7000 rpm. The films were subsequently annealed at 170° C. for 12 hours under a high vacuum (˜10⁻⁸ Torr). The cylindrical morphology of the block copolymer self-assembly was revealed by transmission electron microscopy (TEM). The FIG. 1 shows a transmission electron micrograph of a film, where the PBpin block is susceptible to staining with ruthenium tetroxide and appear dark in the TEM image. From the micrograph, the domain spacing of the cylinders was 26 nm, demonstrating the capability of BCP self-assembly to generate sub-30 nm features.

### Example 3

This example was conducted to demonstrate the doping of Si substrates via spike-rapid thermal annealing (RTA) of dopant polymer films. Diffusion of dopants from the block copolymer thin films into the underlying Si substrates was achieved via spike-RTA. To achieve discrete doping, 20-nm thick films were chosen such that the films only contained one layer of cylinders. The films were annealed at 170° C. for 12 hours under a high vacuum (˜10⁻⁸ Torr) as described previously. Then, the substrates were thermally annealed at 950-1050° C. under an inert atmosphere of N2 from room temperature to different temperatures at 100° C./s, held at these temperatures for 160 seconds and then cooled down rapidly to room temperature.

### Example 4

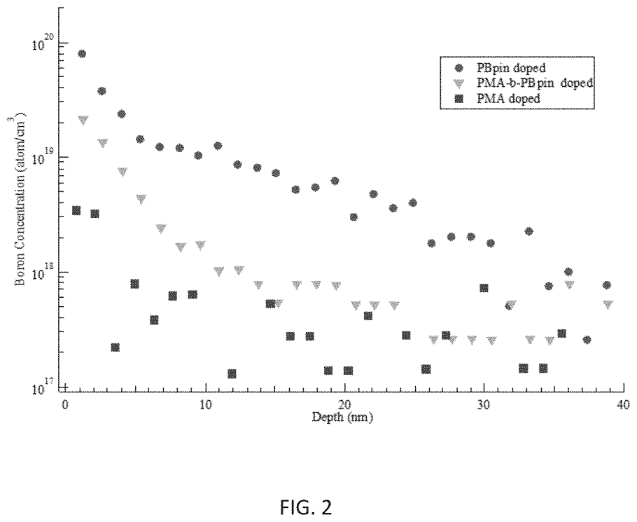

This example was conducted to characterize the dopant distribution in the silicon substrate. The boron depth profiles in the silicon substrate annealed at 1050° C. for 1 second were determined by secondary ion mass spectrometry (SIMS). FIG. 2 is a graph showing boron concentration with depth with control samples of PBpin and poly(methyl acrylate) (PMA) homopolymers.

Silicon substrates were doped with either the poly(methyl acrylate), the PBpin polymer or the block copolymer prepared in Example 1. The boron-containing homopolymer PBpin demonstrated the highest boron concentration and the control group doped with PMA thin films showed the lowest boron concentration that is consistent with background concentration of boron in the silicon substrate. For the block copolymer doped substrate, the concentration was between PBpin and PMA homopolymers with the surface boron concentration is 3×10¹⁹ atoms/cm³. Considering the volume fraction (24%) of the PBpin block in the BCP, the effective local surface concentration is 1.3×10²⁰ atoms/cm³. The boron concentration drops down to 5×10¹⁸ atoms/cm³ (the boron density of conventional 10 mΩ cm substrates) at 5 nm, indicating an ultra-shallow junction. Such ultra-shallow junctions cannot be easily manufactured via ion implantation.

In summary, the boron concentration in the substrate (derived from annealing the block copolymer) ranges from 3×10¹⁹ atoms/cm³ to 5×10¹⁸ atoms/cm³ at a depth of less than 5 nanometers.

The diffusion of boron into the substrate is almost isotropic so the cylindrical morphology was transferred from the thin film to the substrate, but broadened due to the thermal diffusion. By integrating the boron concentration, the areal dosage is 1.17×10¹³ atom/cm². It is worth noting that these concentrations are relevant for metal-oxide-semiconductor field-effect transistors (MOSFETs). The channel uses a dopant concentration of 10¹⁸-10¹⁹ atom/cm³, and source/drain contacts use a dopant concentration of 10²⁰-10²¹ atom/cm³.

### Example 5

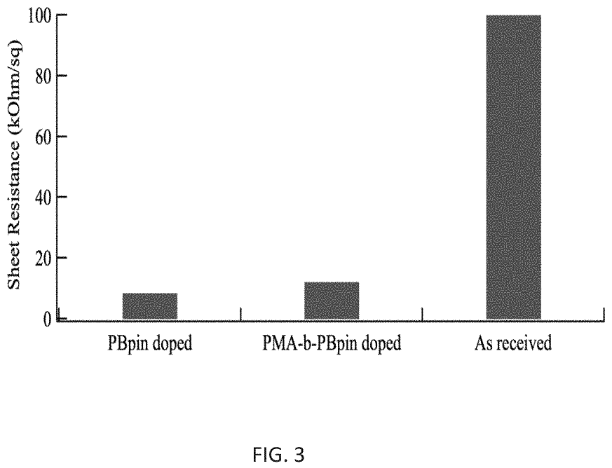

The comparison of sheet resistance between homogeneous and patterned doping of Si substrates is shown in the FIG. 3. The substrate doped by homopolymer PBpin has the lowest sheet resistance because of its large boron source. The block copolymer doped substrate has a sheet resistance of 12.2 kΩ/sq, which is significantly smaller than the as-received wafer, indicating the successful diffusion and activation of the boron atoms in Si.

Controlling of dopant distribution in semiconductors is desirable for improving device performance as they are scaled down to sub-100 nm. While monolayer doping, contact doping and other techniques can controllably achieve ultra-shallow junctions (sub-5 nm), they fall short of the need to confine dopants laterally. Single ion implantation, on the other hand, can achieve deterministic doping by placing dopant atoms precisely into the semiconductor one by one, but the scalability is problematic due to its prohibitive cost and low throughput. Multiple doping steps with same or different dopant may also be conducted to achieve the target doping profile for a functional device.

In this disclosure, lateral confinement of dopants is achieved by block copolymer self-assembly, and control in the z direction is enabled by rapid thermal annealing. Specifically, dopant atoms are covalently bonded to the polymer chains of the minority block so dopants atoms are confined in the nanodomains of the minority block in thin films. Incorporating dopant atoms via covalent bonding in copolymers allows for accessing smaller and a wide range of morphologies (cylinder, lamellae, sphere and others. The domain spacing can be tuned by varying the block copolymer molecular weight, volume fraction and backbone chemistry. It also permits the control of dopant dosage, lateral distribution and junction depth by changing the BCP composition and spike-RTA conditions. The versatility of this method also allows for other dopant atoms and substrates by changing the polymer chemistry.

Moreover, unlike conventional block copolymer lithography and ion implantation, this strategy simplifies the process and cuts down the cost. Compared to other techniques involving RTA, such as monolayer doping, no capping layer is needed.

What is claimed is:

1. A method for doping a substrate, comprising:
disposing a composition comprising a dopant-containing copolymer and a solvent on a substrate; where the dopant-containing copolymer comprises a first dopant; and
annealing the substrate at a temperature of 750 to 1300° C. for 0.1 second to 24 hours to diffuse a dopant into the substrate;
wherein the dopant-containing copolymer comprises a non-dopant-containing polymer and a dopant-containing polymer; and where the dopant-containing polymer is a polymer having a covalently or ionically bound dopant atom and is present in a smaller volume fraction than the non-dopant-containing polymer.

2. The method of claim 1, further comprising doping the substrate with a second dopant, which is different from the first dopant.

3. The method of claim 1, wherein a dopant is selected from boron, phosphorus, arsenic, bismuth, antimony, bismuth, lithium and gallium.

4. The method of claim 1, wherein the substrate is a semiconducting substrate and has a 2-dimensional or a 3-dimensional topography.

5. The method of claim 4, wherein the substrate comprises one or more of silicon, gallium and germanium.

6. The method of claim 1, wherein a single annealing step is performed.

7. The method of claim 1, wherein the dopant is diffused into the substrate to a depth of less than or equal to 10 nanometers.

8. The method of claim 1 wherein the annealing step is performed in an inert atmosphere and/or in an oxidizing atmosphere.

9. The method of claim 1, wherein the copolymer is a block copolymer and comprises an acrylate block and a block comprising a dopant.

10. The method of claim 9, where the block comprising the dopant is poly(4-(4,4,5,5-tetramethyl-1,3,2-dioxaborolan-2-yl)benzyl acrylate).

11. The method of claim 1, where the annealing is effective to remove char from the substrate.

12. A composition comprising:
a dopant-containing copolymer; wherein the dopant-containing copolymer comprises a non-dopant-containing polymer and a dopant-containing polymer; and where the dopant-containing polymer is a polymer having a covalently bound dopant atom and is present in a smaller volume fraction than the non-dopant-containing polymer; and
a solvent.

13. The composition of claim 12, where the dopant-containing polymer is poly(4-(4,4,5,5-tetramethyl-1,3,2-dioxaborolan-2-yl)benzyl acrylate).

14. The composition of claim 13, where the poly(4-(4,4,5,5-tetramethyl-1,3,2-dioxaborolan-2-yl)benzyl acrylate) is endcapped with a dithioester.

15. The composition of claim 12, where the dithioester is 2-(dodecylthiocarbonothioylthio)-2-methylpropionic acid).

16. A method comprising:
mixing in a solvent, a reactive species with an unsaturated group that is devoid of a dopant, a dopant-containing monomer with an unsaturated group, an initiator and a reversible addition fragmentation chain transfer agent; and
reacting the reactive species with the unsaturated group that is devoid of a dopant, the dopant-containing monomer with the unsaturated group, the initiator and the reversible addition fragmentation chain transfer agent to form a copolymer.

17. The method of claim 16, where the copolymer comprises a first polymer that does not comprise a dopant and a second polymer that comprises a dopant.

18. The method of claim 17, where the copolymer is a block copolymer.

19. The method of claim 17, where the dopant is boron or phosphorus.
